(19) United States
(12) Patent Application Publication
(10) Pub. No.: US 2004/0256215 A1
(43) Pub. Date: Dec. 23, 2004

(54) Sputtering chamber liner

(76) Inventors: David Stebbins, Spring Green, WI (US); Roger Stanek, Spring Green, WI (US); Klaus Hartig, Avoca, WI (US)

Correspondence Address: Eric J. Snustad, Fredrikson & Byron, P.A., Suite 4000, 200 South Sixth Street, Minneapolis, MN, 55402-1425, US

(21) Appl. No.: 10/823,500

(22) Filed: Apr. 12, 2004

Related U.S. Application Data
(60) Provisional application No. 60/462,643, filed on Apr. 14, 2003.

(51) Int. Cl. C23C 14/00; C23C 14/32; C25B 9/00

(52) U.S. Cl. 204/192.1; 204/298.01; 204/298.02

(57) ABSTRACT

A liner for a sputtering chamber is provided. The liner is adapted to reduce spalling of sputtered coating (overcoat) from interior surfaces of the chamber. The liner can be mounted adjacent a selected interior surface of the chamber. The liner is preferably removable. Also provided are sputtering chambers in which the present liners are mounted, and sputtering methods wherein the present liners are used.

### CROSS REFERENCE TO RELATED APPLICATIONS

The present application is a continuation of provisional U.S. patent application filed Apr. 14, 2003 and assigned Ser. No. 60/462,643, the entire disclosure of which is incorporated herein by reference.

### FIELD OF THE INVENTION

The present invention relates to depositing thin films onto substrates. More particularly, this invention relates to depositing thin films by sputter deposition.

### BACKGROUND OF THE INVENTION

Sputter deposition (i.e., sputtering) is a well known process for applying thin films onto substrates. Generally speaking, the sputtering process occurs within a sputtering chamber having a sputtering cavity in which a controlled (e.g., vacuous) environment can be established. At least one sputtering target comprising material to be deposited upon a substrate is positioned in the chamber. A power supply is operatively connected to the target to apply an electric (e.g., cathodic) charge to at least a portion of the target. A relatively positively charged anode is commonly positioned in the chamber proximate the target. The chamber is evacuated and a gaseous atmosphere is delivered to the chamber. The electrodes are energized to establish a plasma in the chamber. Charged ions (e.g., positively charged ions) from the plasma bombard the target, causing particles of target material to be ejected on essentially an atom-by-atom basis. While most of these particles are deposited upon a substrate positioned in the chamber, a significant amount of sputtered material (commonly about 5-10% of the total sputtered material) is deposited upon interior surfaces of the chamber.

It is common to include magnets behind the target to help shape and focus the plasma in an area adjacent the sputtering surface of the target. This well known process is generally referred to as “magnetron sputtering.” Magnetron sputtering equipment is commercially available from a variety of sources (e.g., BOC Coating Technology and Leybold Vakuum). Useful sputtering equipment (e.g., chambers) and processes are disclosed in U.S. Pat. No. 4,166,018 (Chapin), the entire teachings of which are incorporated herein by reference.

As a result of the aforementioned ion bombardment, sputtered particles of target material are emitted away/ejected from the target, initially traveling in a direction generally perpendicular to the target surface from which they came. As a result of gas scattering, these emitted/ejected particles are distributed in essentially all directions within the chamber. Thus, not all of the sputtered material is deposited upon the substrate, as noted above. Rather, only about 90-95% of the total sputtered material is deposited upon the substrate. The rest of the sputtered material is deposited upon the exposed interior surfaces inside the chamber (upon chamber walls, shields, end blocks, anodes, gas distribution pipes, etc.). This phenomenon is referred to herein as “contamination”, “condensation”, or “overcoating”. The coating that builds-up on the interior surfaces of the chamber is referred to herein as a “contamination layer, “condensate”, or an “overcoat”. Skilled artisans will appreciate that the contamination layer builds-up more rapidly at higher sputtering rates.

The growth of a contamination layer can pose significant problems. For example, it accounts for a certain amount of lost coating material. It also necessitates periodic removal of contamination from the interior surfaces of the chamber. Contamination removal is extremely difficult and time consuming. Contamination removal accounts for substantial periods of process downtime. This is terribly inefficient from the standpoints of productivity and economics, particularly given the staggering cost of industrial sputtering lines (which commonly cost many millions of dollars).

Further, flakes tend to spall from the contamination layer during the normal heating and cooling cycles of a sputtering chamber. The vacuous sputtering chamber heats up during sputtering, and this causes the contamination layer to heat up as well. When sputtering is stopped and the chamber is shut down, the chamber and the contamination layer cool down. Flakes commonly then begin to spall from the contamination layer (particularly in chambers where dielectric films are deposited). This is believed to be caused at least in part by differences between the thermal expansion coefficient of the chamber surfaces and that of the material being sputtered.

Thus, when the chamber undergoes temperature change, the contamination layer expands and contracts at a thermal expansion rate that depends on the thermal expansion coefficient of the sputtered material. At the same time, the chamber surfaces expand and contract at a thermal expansion rate that depends on the thermal expansion coefficient of the material from which the chamber surfaces are formed. It is surmised that when these rates are substantially different (e.g., in chambers where dielectric films are deposited), the resulting stress on the contamination layer causes flakes to spall from the contamination layer. These flakes can fall upon the substrate being coated, causing damage (e.g., inclusions and/or pinholes) to the freshly-deposited coating on the substrate.

Once a chamber is shut down (e.g., to change targets) and spalling begins, sputtering is typically not resumed until the shower of spalling flakes subsides. Unfortunately, spalling may continue for a substantial period of time once it begins (on the order of 1-2 hours in some cases). Given the astronomical cost of industrial sputtering lines, the resulting loss in productivity is terribly inefficient, as noted above. Further, when one considers that industrial sputtering lines are equipped with up to 36 targets (each requiring periodic replacement), the magnitude of the problem can be acutely appreciated.

Attempts have been made to curtail the spalling of a contamination layer from the interior surfaces of a sputtering chamber. For example, BOC Coating Technology (“BOC”) produces sputtering chambers in which selected interior surfaces are provided with copper plates cladded with stainless steel wire grid shields. For example, each shield may be a grid of stainless steel wire having a diameter of about 1-1.5 mm, with a significantly larger distance between adjacent, parallel wires. Commonly, the wire grid shields are spot welded to the interior faces of the copper plates, but are not thermally coupled to any sort of heat sink. Since sputtering is a vacuum process (i.e., it is performed in a vacuous chamber), the wire grid shields become quite hot during sputtering.

The BOC wire grid shields are designed to break-up stress within the contamination layer (such that large particles of contamination are less likely to fall) and to provide greater surface area than equivalent planar surfaces, allowing them to retain more sputtered material than the planar interior walls of a sputtering chamber. BOC indicates that the shields in one of its chambers can be removed and cleaned, following venting, in a short amount of time. Thus, BOC provides shields that are designed to retain more sputtered material than planar surfaces and are said to be quickly removable and cleanable. However, these shields are formed of steel. Thus, while they may decrease maintenance time, they do not address the problems associated with differential thermal expansion.

Further, the process of cleaning these shields is less than ideal. For example, the wire grid can be cleaned using a high speed stream of pressurized air. However, pressurized air may not completely remove contamination from the wire grid. Moreover, pressurized air may contain trace amounts of oil, which may end up on the wire shields, potentially causing contamination of the chamber in which the shields are mounted. Sandblasting can also be used to clean the wire shields. Sandblasting is likely to more thoroughly remove contamination from the wire grid. However, there is a possibility that sand particles may become lodged in the wire grid. Thus, it can be appreciated that wire grid shields are less than ideal in some respects.

It would be desirable to provide a sputtering chamber liner that allows expansion and contraction of sputtered material on the liner without the occurrence of substantial spalling of such sputtered material from the liner during cycles of the sputtering process.

### SUMMARY OF THE INVENTION

In certain embodiments, the invention comprises an improvement provided in a sputtering chamber for applying thin films onto substrates. The chamber has a sputtering cavity in which a controlled (e.g., vacuous) environment can be established. A target is positioned in the sputtering cavity and is adapted to deposit a sputtered material having a first thermal expansion rate. A power supply is operatively connected to the target to apply an electric (e.g., cathodic) charge to at least a portion of the target. In the present embodiments, the improvement comprises a removable liner that is positioned adjacent a selected interior surface of the chamber and is adapted to receive an overcoat of the sputtered material that otherwise would be deposited on the selected interior surface of the chamber. In the present embodiments, the liner preferably is adapted to expand and contract with the overcoat at the first thermal expansion rate, thereby substantially eliminating spalling of particles of the overcoat from the liner.

In certain embodiments, the invention provides a puttering chamber for applying thin films onto substrates. The chamber comprises a sputtering cavity in which a controlled (e.g., vacuous) environment can be established. A target is positioned in the sputtering cavity and is adapted to deposit a sputtered coating having a first thermal expansion rate. A power supply is operatively connected to the target for applying an electric (e.g., cathodic) charge to at least a portion of the target. A removable liner is positioned adjacent a selected interior surface of the chamber. The liner has a major surface that is oriented generally toward the target and is adapted to receive an overcoat of the sputtered coating that otherwise would be deposited on the selected interior surface of the chamber. In the present embodiments, the liner preferably is adapted to expand and contract with the overcoat at the first thermal expansion rate, thereby substantially eliminating spalling of particles of the overcoat from the liner.

In certain embodiments, the invention provides a sputtering chamber for applying thin films onto substrates. The chamber has a sputtering cavity in which a controlled (e.g., vacuous) environment can be established. The chamber includes a target that is positioned in the cavity and is operatively connected to a power supply adapted to apply an electric (e.g., cathodic) charge to at least a portion of the target. The chamber includes a removable liner positioned adjacent a selected interior surface of the chamber. In the present embodiments, the liner preferably comprises a mat (e.g., a flexible, soft mat) of fibrous material.

In certain embodiments, the invention provides a sputtering chamber for applying thin films onto substrates. The chamber has a sputtering cavity in which a controlled (e.g., vacuous) environment can be established. The chamber includes a target that is positioned in the cavity and is operatively connected to a power supply adapted to apply an electric (e.g., cathodic) charge to at least a portion of the target. The chamber includes a removable liner positioned adjacent a selected interior surface of the chamber. In the present embodiments, the liner preferably comprises a non-woven web of fibers.

In certain embodiments, the invention provides a sputtering chamber for applying thin films onto substrates. The chamber has a sputtering cavity in which there is established a controlled (e.g., vacuous) environment comprising a sputtering gas. The chamber includes a target that is positioned in the cavity and comprises a sputterable target material selected in conjunction with the sputtering gas to facilitate deposition of a transparent dielectric film. The chamber includes a power supply operatively connected to the target to apply an electric (e.g., cathodic) charge to at least a portion of the target. A removable liner is positioned adjacent a selected interior surface of the chamber and is adapted to catch an overcoat of the transparent dielectric film, which overcoat otherwise would be deposited on the selected interior surface of the chamber. In the present embodiments, the liner preferably comprises a plurality of ceramic fibers.

In certain embodiments, the invention provides a sputtering chamber for applying thin films onto substrates. The chamber has a sputtering cavity in which a controlled (e.g., vacuous) environment can be established. The chamber includes a target that is positioned in the cavity and is operatively connected to a power supply adapted to apply a cathodic charge to at least a portion of the target. The chamber includes a removable liner positioned adjacent a selected interior surface of the chamber. In the present embodiments, the liner preferably comprises a plurality of metal and/or metal alloy fibers.

In certain embodiments, the invention provides a method of applying thin films onto substrates. The method comprises providing a sputtering chamber having a sputtering cavity in which there is established a controlled (e.g., vacuous) environment comprising a sputtering gas. The chamber includes a target positioned in the cavity. The target is adapted to deposit a sputtered material. The chamber includes a power supply operatively connected to the target to apply an electric (e.g., cathodic) charge to at least a portion of the target. The chamber includes at least one substrate support carrying a substrate within the sputtering cavity. The chamber includes a removable liner positioned adjacent a selected interior surface of the chamber. The liner comprising a mat (e.g., a soft mat) of fibrous material. The method comprises sputtering the target to deposit a film of the sputtered material upon the substrate, whereby an overcoat of the sputtered material is received by the liner.

One aspect of the invention relates to a sputtering chamber for applying thin films on substrates. The sputtering chamber includes a sputtering cavity in which a controlled (e.g., vacuous) environment can be established. A target is positioned within the sputtering cavity and is adapted to deposit a sputtered material having a first thermal expansion rate. A power supply is operatively connected to the target to apply an electric (e.g., cathodic) charge to at least a portion of the target. The sputtering chamber includes a removable liner positioned adjacent a selected interior surface of the sputtering chamber. The liner is adapted to catch an overcoat of sputtered material that would otherwise be deposited on the selected interior surface of the chamber. In the present aspect of the invention, the liner preferably is adapted to yield readily to expansion and contraction of the overcoat at the first thermal expansion rate. Thus, substantial spalling of particles of overcoat from the liner is prevented.

In another aspect, the invention provides a sputtering chamber for applying thin films on substrates. The chamber includes a sputtering cavity within which a controlled (e.g., vacuous) environment can be established. A target is positioned within the sputtering cavity and is adapted to deposit a sputtered coating having a first thermal expansion rate. A power supply is operatively connected to the target to apply an electric (e.g., cathodic) charge to at least a portion of the target. A removable liner is positioned adjacent a selected interior surface of the sputtering chamber. The liner has a major surface oriented toward the target, such that it is adapted to catch an overcoat of sputtered coating that would otherwise be deposited on the selected interior surface of the chamber. In the present aspect of the invention, the liner preferably is adapted to yield readily to expansion and contraction of overcoat at the first thermal expansion rate. Thus, substantial spalling of particles of overcoat from the liner is prevented.

A sputtering chamber for applying thin films on substrates is provided in still another aspect of the invention. The chamber comprises a floor, a plurality of sidewalls, and a ceiling together defining a sputtering cavity. A controlled environment can be established within the sputtering cavity. The chamber includes a sputtering target positioned within the cavity. The target is operatively connected to a power supply that is adapted to apply an electric charge to at least a portion of the target. The chamber includes a removable liner positioned adjacent a selected interior surface of the chamber. In the present aspect of the invention, the liner preferably comprises a mat (e.g., a soft mat) of fibrous material.

Yet another embodiment of the invention provides a sputtering chamber for applying thin films on substrates. The chamber comprises a plurality of interior surfaces together defining a sputtering cavity. A controlled environment can be established within the sputtering cavity. The chamber includes a sputtering target positioned within the sputtering cavity. The target is operatively connected to a power supply that is adapted to apply an electric charge to at least a portion of the target. The chamber includes a removable liner positioned adjacent a selected interior surface of the sputtering chamber. In the present embodiment, the liner preferably comprises a non-woven web of fibers.

Still another embodiment of the invention provides a sputtering chamber comprising a plurality of interior surfaces together defining a sputtering cavity. A controlled environment comprising a sputtering gas can be established within the sputtering cavity. The chamber includes a sputtering target positioned within the cavity. The target comprises a target material selected in conjunction with the sputtering gas to facilitate deposition of a sputtered ceramic coating. The chamber includes a power supply operatively connected to the target to apply an electric charge to at least a portion of the target. A disposable liner is positioned adjacent a selected interior surface of the chamber and is adapted to catch an overcoat of the sputtered ceramic coating that would otherwise be deposited on the selected interior surface of the chamber. In the present embodiment, the liner preferably comprises a mat (e.g., a soft mat) comprising, consisting essentially of, or consisting of ceramic fibers.

In a further aspect, the invention provides a method of applying thin film on substrates. The method involves providing a sputtering chamber comprising a plurality of interior surfaces together defining a sputtering cavity. A sputtering target is positioned within the chamber and is adapted to deposit a sputtered material. The chamber includes a power supply operatively connected to the target to apply an electric charge to at least a portion of the target. The chamber includes at least one substrate support carrying a substrate within the sputtering cavity. The chamber includes a removable liner positioned adjacent a selected interior surface of the chamber. The liner comprises a mat (e.g., a soft mat) of fibrous material. The target is sputtered to deposit a coating of the sputtered material upon the substrate. An overcoat of the sputtered material is thereby deposited upon the liner.

Another aspect of the invention provides a method of applying thin film onto substrates. The method involves providing a sputtering chamber having a sputtering cavity. A controlled environment is established/exists within the sputtering cavity. A sputtering target is positioned within the cavity and is adapted to deposit a sputtered material. The chamber includes a power supply operatively connected to the target to apply an electric charge to at least a portion of the target. The chamber includes at least one substrate support carrying a substrate within the sputtering cavity. The chamber includes a removable liner mounted adjacent a selected interior surface of the chamber. The target is sputtered to deposit a coating of the sputtered material upon the substrate. An overcoat of the sputtered material is thereby deposited upon the liner. In the present aspect of the invention, the liner is later removed from the chamber, and is replaced by positioning a second liner adjacent the selected interior surface of the chamber.

In certain embodiments, the invention provides a sputtering chamber for applying thin films onto substrates. The chamber has a sputtering cavity in which a controlled (e.g., vacuous) environment can be established. The chamber includes a target positioned in the cavity. The target is operatively connected to a power supply adapted to apply an electric charge to at least a portion of the target. The chamber includes a removable liner positioned adjacent a selected interior surface of the chamber. In the present embodiments, the liner preferably comprises a plurality of metal alloy fibers. In some embodiment of this nature, the liner comprises, consists essentially of, or consists of stainless steel fibers.

In certain embodiments, the invention provides a sputtering chamber for applying thin films onto substrates. The chamber has a sputtering cavity in which a controlled (e.g., vacuous) environment can be established. The chamber includes a target positioned in the cavity. The target is operatively connected to a power supply adapted to apply an electric charge to at least a portion of the target. The chamber includes a removable liner positioned adjacent a selected interior surface of the chamber. In the present embodiments, the liner preferably comprises a plurality of fibers.

In certain embodiments, the invention provides a sputtering chamber for applying thin films onto substrates. The chamber has a sputtering cavity in which a controlled environment can be established. In the present embodiments, the chamber includes two rotary targets mounted in the cavity below a ceiling of the chamber. The targets are operatively connected to at least one power supply adapted to apply an electric charge to at least a portion of each target. The chamber includes a removable liner positioned adjacent a selected interior surface of the chamber. In the present embodiments, the selected interior surface preferably comprises a central region of the chamber's ceiling. The liner in the present embodiments preferably comprises a mat of fibrous material. Preferably, in the present embodiments, the two targets are spaced apart such that the liner adjacent the central region of the chamber's ceiling is exposed to material sputtered in the chamber. Further, the liner in these embodiments preferably is mounted adjacent the selected interior surface by a plurality of aluminum fasteners each having a roughened surface exposed to material sputtered in the chamber.

### BRIEF DESCRIPTION OF THE DRAWINGS

FIG. 1 is a schematic cross-sectional side view of a sputtering chamber in accordance with certain embodiments of the present invention.

FIG. 2 is a schematic partially broken-away cross-sectional side view of a liner in accordance with certain embodiments of the invention.

FIG. 3 is a schematic enlarged perspective view of a liner fiber in accordance with certain embodiments of the invention.

FIG. 4 is a schematic cross-sectional side view of a liner having a central core according to certain embodiments of the invention.

FIG. 5 is a schematic cross-sectional side view of a liner having a plurality of layers according to certain embodiments of the invention.

FIG. 6 is a schematic cross-sectional side view of a sputtering chamber in which a liner is mounted in accordance with certain embodiments of the invention.

FIG. 7 is a schematic cross-sectional side view of a sputtering chamber in which two liners are mounted in accordance with certain embodiments of the invention.

FIG. 8 is a schematic partially broken-away, exploded perspective view of an assembly for mounting a liner to an interior surface of a sputtering chamber in accordance with certain embodiments of the invention.

FIG. 9A is a schematic partially broken-away side view of a fastener, embodied in the form of a fastening bar, for mounting a liner adjacent an interior surface of a sputtering chamber in accordance with certain embodiments of the invention.

FIG. 9B is a schematic side view of a fastener for mounting a liner adjacent an interior surface of a sputtering chamber in accordance with certain embodiments of the invention.

### DETAILED DESCRIPTION OF PREFERRED EMBODIMENTS

The following detailed description is to be read with reference to the drawings, in which like elements in different drawings have been given like reference numerals. The drawings, which are not necessarily to scale, depict selected embodiments and are not intended to limit the scope of the invention. Skilled artisans will recognize that the examples given have many useful alternatives that fall within the scope of the invention.

In certain embodiments, the invention involves a sputtering chamber having a sputtering cavity in which a controlled (e.g., vacuous) environment can be established. Typically, the chamber comprises a plurality of interior surfaces together defining the sputtering cavity. In certain embodiments, the chamber comprises a floor, at least one sidewall, and a ceiling (or “cover” or “top lid”) together defining the sputtering cavity. It will be appreciated that the terms ceiling, cover, and top lid refer equally well to the top wall of the chamber or to any other structure (e.g., a plate or another downwardly-facing body) mounted below the top wall of the chamber. The same is true of the terms sidewall, floor, and the like.

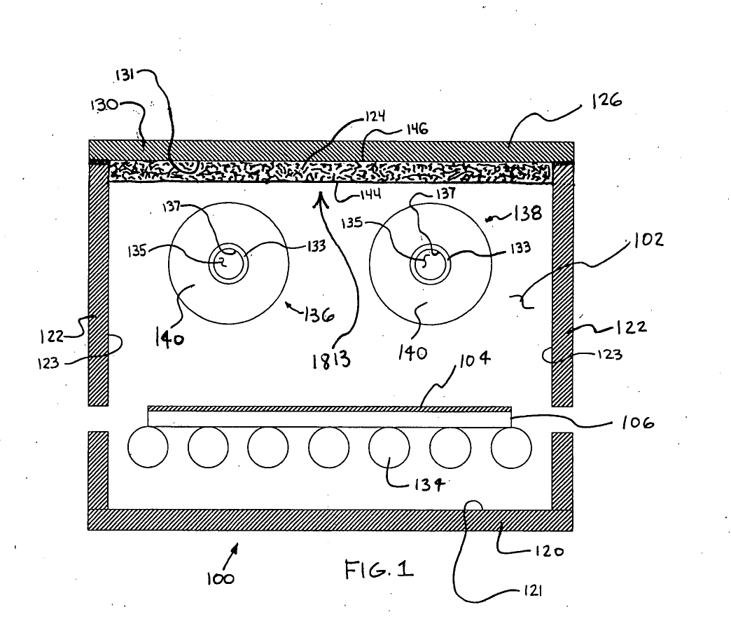

FIG. 1 is a schematic cross-sectional illustration of a sputtering chamber 100 in accordance with certain embodiments of the invention. Here, the chamber 100 includes a base (or “floor”) 120, a plurality of sidewalls 122, and a cover 130 together bounding the sputtering cavity 102. Preferably, the sputtering cavity 102 is defined together by the interior surface 121 of the base 120, the interior surfaces 123 of the sidewalls 122, and the interior surface 131 of the cover 130.

The sputtering chamber preferably comprises a substrate support defining a path of substrate travel extending through the chamber. Preferably, the path of substrate travel extends generally or substantially horizontally through the chamber. The path of substrate travel preferably extends entirely through the chamber between a chamber inlet 888 and a chamber outlet 889. In embodiments wherein the sputtering chamber is connected to other chambers, the path of substrate travel preferably extends through each of the chambers.

During sputtering, the substrate is commonly conveyed through the chamber at speeds between about 100-500 inches per minute. In certain embodiments, the substrate is a sheet of glass and is on (e.g., positioned on top of) the substrate support during conveyance. In some embodiments of this nature, other sheets of glass are also positioned on the support, such sheets of glass being spaced apart from one another on the support and conveyed in such a spaced-apart configuration. While the illustrated substrate support comprises a plurality of transport rollers, it is to be appreciated that other types of substrate supports can be used.

The present sputtering chamber can be connected to one or more other deposition chambers (e.g., other sputtering chambers and/or chambers adapted for carrying out other film deposition process). In certain embodiments, the present sputtering chamber is part of a series of connected deposition chambers. For example, there can be provided a line of connected deposition chambers (i.e., a coating line). Such a coating line may comprise a series of chambers aligned and connected so that a substrate (or a plurality of spaced-apart sheet-like substrates, such as glass sheets) horizontally supported on spaced-apart transport rollers can be conveyed through the chambers of the line sequentially. Preferably, such a coating line includes narrow evacuated tunnels, which connect adjacent chambers, through which the horizontally-oriented substrate is conveyed from one chamber to the next. During film deposition, the substrate is typically conveyed through all the chambers of such a coating line.

Preferably, the substrate support is configured for maintaining (e.g., supporting) a substrate (e.g., a sheet-like substrate) in a generally or substantially horizontal position while the substrate is being coated (e.g., during conveyance of the substrate through the chamber). Thus, the support desirably is adapted to convey a sheet-like substrate, and preferably multiple sheet-like substrates spaced-apart from one another, while maintaining the/each substrate in a generally or substantially horizontal orientation (e.g., wherein a top major surface of the/each substrate is oriented upwardly while a bottom major surface of the/each substrate is oriented downwardly).

The illustrated substrate support comprises a plurality of spaced-apart transport rollers. The transport rollers in certain embodiments are spaced generally or substantially evenly apart along substantially the entire path of substrate travel. Typically, at least one of the rollers is rotated (e.g., by energizing a motor operably connected to the roller) such that the substrate is conveyed through the chamber along the path of substrate travel. When the substrate is conveyed over such rollers, the bottom surface of the substrate is in direct physical (i.e., supportive) contact with the rollers. Thus, certain methods of the invention involve a glass sheet and a substrate support comprising a plurality of spaced-apart transport rollers, wherein the method comprises rotating at least one of the transport rollers to facilitate conveyance of the glass sheet, such that the bottom major surface of the glass sheet comes into direct physical contact with the rollers during conveyance.

In the embodiment of FIG. 1, the sputtering chamber 100 includes a substrate support defined by a plurality of spaced-apart transport rollers 134. The illustrated rollers 134 are spaced substantially uniformly along a length (e.g., along substantially the entire length) of the chamber 100 to define a continuous path of substrate travel extending through the chamber (i.e., through the cavity 102). Each roller 134 preferably extends across the entire width of the chamber. Preferably, each transport roller is adapted to accommodate large-area substrates (e.g., substrates each having a width of at least about 0.5 meter, perhaps preferably at least about 1 meter, perhaps more preferably at least about 1.5 meters, such as between about 2 meters and about 4 meters, and in some cases at least about 3 meters). The length of each roller (in some cases, the length of a substrate-support portion of each roller) is preferably within one or more of the noted ranges. Thus, the chamber desirably is adapted for applying thin films onto large-area substrates.

The rollers 134 can be of any conventional structure. Good results have been obtained using cylindrical (e.g., aluminum) rollers about which a rope (e.g., of Kevlar™) has been wound (e.g., spirally), such that the substrate 106 comes into direct, supportive contact with the rope. The rollers 134 are used to advance substrates 106 through the sputtering cavity 102. Thus, FIG. 1 illustrates a substrate 106 moving substantially horizontally over the rollers 134 (i.e., from left to right, or from right to left, as seen in FIG. 1).

In the embodiment of FIG. 1, the sputtering chamber 100 is provided with two cylindrical magnetron cathodes (i.e., Cmags). As is well known in the present art, a cylindrical cathode commonly includes a cylindrical, rotatable target, a static (i.e., non-rotational) downwardly-oriented magnet bar assembly within the rotatable target, a drive system for rotating the target, and one (e.g., a cantilever) or two end blocks. In FIG. 1, a first cylindrical target 136 and a second cylindrical target 138 are mounted in the cavity 102. Thus, the chamber 100 illustrated in FIG. 1 comprises two rotary targets mounted below the ceiling of the chamber. The two targets are spaced apart such that a central surface region 1813 defined by the ceiling (which here is the top wall of the chamber) is not concealed by the two rotary targets. The illustrated liner is mounted adjacent (e.g., carried against) the exposed central surface region 1813 of the chamber's ceiling. In FIG. 1, the liner is shown covering the whole ceiling. In other cases, the liner covers a central surface region defined by the ceiling, but does not cover the entire ceiling. For example, in some cases, the liner covers substantially the entire ceiling other than areas of the ceiling directly above the targets. In other embodiments, the liner covers only an exposed central surface region of the chambers' ceiling (i.e., the liner only covers a central region of the ceiling that would otherwise be exposed, between the two targets, to material sputtered in the chamber).

The chamber 100 can be provided with any number and type(s) of cathodes (e.g., rotary and/or planar). Useful sputtering equipment is available from well known commercial suppliers, such as BOC Coating Technology (Fairfield, Calif., U.S.A.), Leybold Vakuum GmbH (Cologne, Germany), Bekaert VDS nv (Deinze, Belgium), and Academy Precision Metals (Albuqurque, N.Mex., U.S.A.).

Each sputtering target can comprise sputterable target material of any desired composition. Examples of commonly used metallic target materials include silver, zinc, silicon, titanium, niobium, tin, stainless steel, chromium, zirconium, tantalum, and hafnium. Each target can alternatively comprise target material of an oxide, nitride, carbide, etc. In the embodiment of FIG. 1, the first 136 and second 138 targets can have the same composition or different compositions (e.g., for a co-sputtering process).

In FIG. 1, each illustrated sputtering target includes a backing tube 133 carrying a layer of sputterable target material 140. A magnet bar assembly is commonly provided in the cylindrical cavity 135 bounded by the interior surface 137 of the backing tube 133. The magnets in these assemblies are used to concentrate plasma adjacent desired erosion areas on the targets. For example, it is generally preferred to concentrate plasma adjacent downwardly-oriented surfaces of the targets. Thus, during sputtering, a magnet bar assembly in each target is preferably retained in a stationary (or substantially stationary), generally downwardly-facing orientation while each target is rotated about its longitudinal axis.

The sputtering chamber preferably includes at least one anode (not shown) positioned adjacent the target(s), as is well known in the present art. In the embodiment of FIG. 1, the targets 136,138 are preferably positioned between two anodes (not shown) that extend horizontally and are generally parallel to the targets 136, 138. As suggested in U.S. Pat. No. 5,645,699, the entire teachings of which are incorporated herein by reference, an intermediate anode (not shown) can be positioned between the targets 136, 138. In certain particularly advantageous embodiments, the chamber is provided with a gas-distribution anode of the nature described in U.S. patent application Ser. No. 10/323,703, the entire teachings of which are incorporated herein by reference.

As is well known, a gas distribution system can be used to supply gas to the sputtering chamber. A variety of conventional gas distribution systems are known in the present art. The distribution system can simply comprise a pair of pipes with a plurality of spaced-apart openings or nozzles oriented generally toward each target. The gas distribution pipes in the chamber are preferably positioned adjacent the target or targets, as is also well known. In certain particularly preferred embodiments, a gas-distribution anode is provided in the chamber, as noted above.

A gaseous sputtering atmosphere is delivered to the cavity 102 by operating the gas distribution system. A power supply coupled to each target can be operated to deliver an electric (e.g., cathodic) charge to each target. Alternatively, a switching power supply can be operated to deliver a cathodic charge alternately to the targets 136, 138. As noted above, the chamber 100 is preferably provided with at least one anode. The electrodes create a D.C., or radio-frequency A.C., field in the chamber. This ionizes the gas and establishes a plasma in the chamber 100. Charged plasma ions (e.g., positively charged ions) bombard the target or targets, causing particles of target material 140 to be ejected from each target. These particles are emitted away from the target, initially traveling in a direction generally perpendicular to the target surface from which they came. Due to gas scattering, these particles are distributed in essentially all directions within the chamber.

The sputtering chamber includes a liner positioned adjacent a selected interior surface of the chamber. The liner is preferably, though not necessarily, removable. In the embodiment of FIG. 1, the liner 124 is positioned adjacent the chamber's ceiling 130. This is particularly advantageous since spalling condensate is most likely to fall upon substrates from the ceiling of a chamber, as the ceiling is directly above the path of substrate travel. The liner 124, however, can be mounted adjacent any interior surface of the chamber 100. For example, the liner can alternatively be positioned adjacent one of the sidewalls 122 of the chamber. Further, more than one chamber surface can be covered with liners. For example, in one embodiment, liners are mounted adjacent all of the interior chamber surfaces that are above the path of substrate travel (e.g., on the ceiling and two confronting sidewalls). Alternatively, multiple liners can be used to cover a single chamber surface. As another alternative, a single liner can be configured to cover multiple chamber surfaces. For example, a liner can be folded or shaped to cover two or more contiguous chamber surfaces.

The liner 124 has generally opposed first 144 and second 146 major surfaces (or faces), which preferably are oriented respectively generally toward and away from the sputtering target or targets. In the embodiment of FIG. 1, the liner 124 is carried directly against the ceiling 130 of the chamber 100, such that the second major surface 146 of the liner 124 abuts (e.g., is contiguous to) the interior surface 131 of the chamber's ceiling 130. Alternatively, the liner 124 can be spaced a desired distance from the ceiling 130, or from any other chamber surface. This may be preferred to prevent gas from being trapped beneath the liner.

In some cases, the first major surface or face 144 of the liner 124 is oriented generally toward the sputtering target or targets 136, 138 in the chamber. The liner 124 is preferably adapted to receive (e.g., catch) an overcoat of sputtered material that otherwise would be deposited on the chamber surface behind (i.e., covered by) the liner 124. For example, in the embodiment of FIG. 1, the liner 124 is adapted to catch sputtered material that would otherwise be deposited upon the chamber ceiling 130. A deposit of condensate accumulates on the liner 124 during sputtering. In fact, a continuous layer of overcoat may build-up on the liner 124 after enough use. Preferably, the liner is removed, discarded, and replaced before or once it gets heavy enough to sag under the weight of the coating it has received. In some embodiments, each liner is replaced every time a sputtering target in the chamber is replaced. While condensate may appear only to accumulate on the surface of the liner, a substantial amount of overcoat may also be retained beneath the surface of the liner.

In certain embodiments, the liner is adapted to expand and contract with the overcoat at the thermal expansion rate of the overcoat without substantial spalling of particles of the overcoat from the liner (in some cases, even when the thermal expansion rate of the overcoat is substantially different than that of the material from which the liner is formed). In some embodiments, this is accomplished by providing a liner having a non-rigid (e.g., soft and pliant) structure, which preferably allows condensate on the surface of the liner to freely expand and contract at the different thermal expansion rates of the various materials that can be sputtered. It is believed that spalling of condensate from existing wire shields is caused at least in part by resistance of the somewhat rigid shield material to expansion and contraction of condensate having a different thermal expansion coefficient than that of the wire from which the shields are formed. Thus, the liner preferably has a non-rigid structure (and/or a thermal expansion rate that approximates that of the material being deposited) that complies readily with expansion and contraction of different condensate materials. Thus, when the overcoat adhered to the liner expands or contracts, the liner does not substantially resist such expansion or contraction (i.e., not enough to cause substantial spalling of particles of the overcoat material). Rather, the liner 124 freely expands and contracts along with the overcoat.

In certain embodiments, the liner comprises a plurality of fibers. Fibers make up a major (i.e., 50% or more) portion and/or percentage (e.g., weight percentage) of the liner in some cases. In certain embodiments, the liner includes fibers and one or more binder materials (e.g., one or more fiber-retaining binder materials). The liner consists essentially of, or consists of, fibers in some cases.

In certain preferred embodiments, the liner 124 comprises a mat (e.g., a soft, non-rigid mat) of fibrous material. A liner of this nature can advantageously comprise very fine, small-diameter fibers. This gives the liner 124 a large effective surface area, which facilitates retention of a great amount of sputtered material. The liner 124 preferably comprises fibers having a much smaller diameter than the wires of known shields. For example, the liner 124 can comprise fibers having a diameter of less than about 300 micrometers. Preferably, the fibers are less than about 50 micrometers in diameter, with fibers having a diameter of less than about 30 micrometers perhaps being optimal. In some embodiments, the liner comprises a mat (or sheet) of ceramic fibers.

When the liner is formed of a plurality of fibers, the thickness of the liner is typically at least 3 fiber diameters. This is believed to facilitate greater retention of sputtered material than existing wire shields, the thickness of which is commonly two wire diameters. The surface area of the liner is increased to improve its capacity for retaining coating. Preferably, the liner 124 has a ratio of thickness to fiber diameter of at least 5 to 1, more preferably at least 10 to 1, and perhaps optimally at least 13 to 1. The liner 124 in certain embodiments comprises extremely fine, small-diameter fibers. In these embodiments, it may be preferable to provide an even greater ratio of liner thickness to fiber diameter. For example, a ratio of at least 30 to 1 may be preferred, and a ratio of at least about 60 to 1 may be particularly preferred.

The thickness of the liner 124 can be varied to suit different applications. When used in a conventional sputtering chamber, a liner thickness of less than about 50,800 micrometers (50.8 mm/2 inches) will typically be suitable. In some embodiments, the liner thickness is between about 1500 micrometers (1.5 mm/0.06 inch) and about 13,000 micrometers (13 mm/0.512 inch). A liner thickness of between about 1000 micrometers (1 mm/0.0394 inch) and about 3175 micrometers (3.18 mm/0.125 inch) is used in some embodiments. Skilled artisans will appreciate that the liner thickness can be varied to meet the requirements of different applications. It is to be understood that the term thickness is used herein, when referring to the liner 124, to mean the distance between the first 144 and second 146 faces of the liner 124.

Preferably, the liner is vacuum compatible, commercially available, and inexpensive. Conjointly, the liner preferably has a high melting point (e.g., at least about 100-200 degrees Celsius, more preferably at least about 500 degrees Celsius, and perhaps optically at least about 1000 degrees Celsius). Preferably, the liner is not a closed-cell material (but rather is a fibrous or open-cell material). In certain embodiments, the liner 124 comprises a sheet of inorganic, amorphous glass fibers. In one embodiment, the liner 124 is a sheet of refractory ceramic fibers (RCF). Suitable RCF sheets are commercially available from various suppliers, such as Vesuvius USA Corp. (Erwin, Tenn., U.S.A.). One suitable RCF sheet product is sold commercially under the trade name CER-WOOL™ Blanket LT. A liner of this nature would have a melting point of about 1590 degrees Celsius or higher.

In certain embodiments, the liner comprises a desired thickness of fibrous material. The entire thickness of such a liner is not required to be fibrous, although this is the case in some embodiments. In certain preferred embodiments, a major thickness (i.e., 50% or more) of the liner is fibrous.

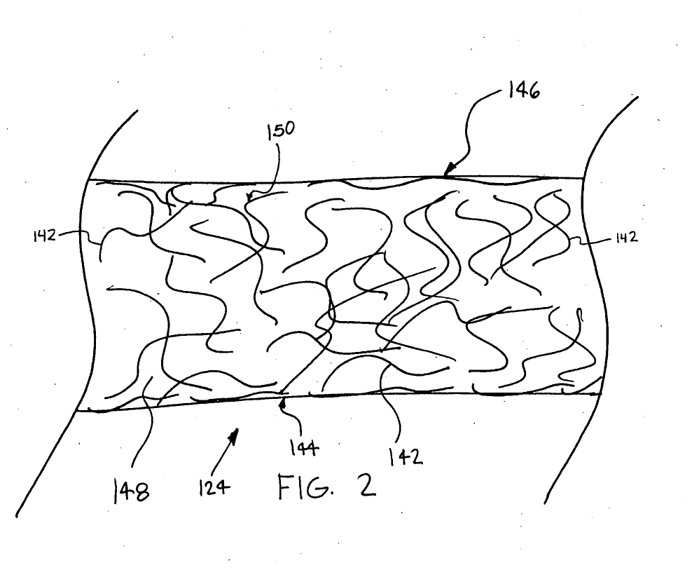

In certain embodiments, the liner 124 comprises a non-woven web of fibers. The fibers in a non-woven web are preferably disposed in a substantially randomly intertangled manner. For example, FIG. 2 is a schematic partially broken-away cross-sectional depiction of a liner 124 comprising fibers 142 disposed in a randomly interlaced pattern. A plurality of these fibers 142 define a first major surface (or face) 144 of the liner 124. Likewise, a plurality of these fibers 142 define a second major surface (or face) 146 of the liner 124. Preferably, the liner 124 is generally sheet like, such that the first 144 and second 146 faces are generally-opposed major faces.

With continued reference to FIG. 2, it can be appreciated that the randomly intertangled fibers 142 define a plurality of interstitial spaces 148. As noted above, some of the particles of sputtered material that do not reach the substrate 106 are deposited on the liner 124. A portion of these particles are deposited on the outer surfaces 150 of the fibers 142 that define the first major surface or face 144 of the liner 124. Others travel through interstitial spaces 148 of the liner 124 and are deposited on the outer surfaces 150 of fibers 142 beneath the first major surface or face 144 of the liner 124. Thus, the interstitial spaces 148 of the liner 124 permit sputtered material to be retained by fibers other than those at the surface or face 144 of the liner 124.

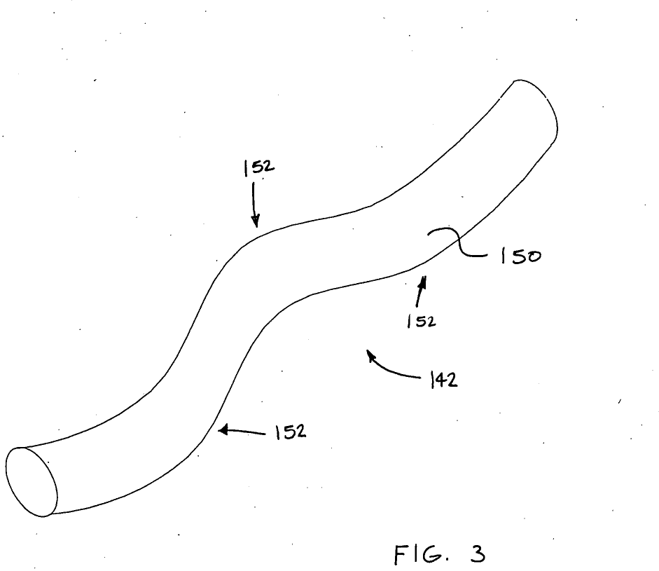

FIG. 3 is an enlarged schematic perspective view of an individual fiber 142 that is characteristic of a plurality of the fibers in the embodiment of FIG. 2. The fiber 142 has an outer surface 150 and at least one bend (preferably a plurality of bends) 152. The illustrated fiber 142 has a generally cylindrical configuration. Of course, this is not a requirement, as the present liner can include fibers of any configuration. The bends 152 in a fiber 142 can facilitate its intertangling with adjacent fibers 142. For example, in embodiments where the liner 124 is simply a mass of fibers (optionally together with a fiber-retaining binder), the bends 152 can help hold the fibers together.

In certain embodiments, a liner comprising a mass of fibers is treated with a fiber-retaining binder. Preferably, the binder is an inorganic binder, such as sodium silicate, which will not exhibit substantial degassing (preferably exhibiting no degassing). These embodiments achieve a liner having particularly good mechanical stability and a less active surface. In certain embodiments, the liner consists essentially of fibers and a desired binder material, such as a fiber-retaining binder material.

In certain embodiments, the liner 124 is produced by: providing a water-glass receptacle containing sodium silicate; positioning a fibrous (e.g., felt-like) liner in the sodium silicate; optionally drawing a vacuum in the receptacle; removing the liner from the receptacle; and thereafter allowing the liner to dry (e.g., hanging it to dry).

The liner can alternatively comprise fibers arranged in a desired pattern. Thus, in certain embodiments, the liner comprises a fabric (e.g., a soft fabric), such as a fabric of interwoven fibers. In some cases, the liner comprises a fabric of matted and/or compressed fibers. In one case, the liner comprises a felt-like fabric. The fibers can be woven, arranged, or formed into any desired pattern. The fibers themselves can be formed of various materials (e.g., ceramic), as described below.

In embodiments wherein the liner comprises a plurality of fibers, the fibers 142 can be formed of various materials. In certain preferred embodiments, the liner 124 includes (e.g., comprises, consists essentially of, or consists of) a plurality of ceramic fibers. For example, these fibers can be formed of aluminum oxide (e.g., Al₂O₃), titanium oxide (e.g., TiO₂), silicon oxide (e.g., SiO₂), calcium oxide (e.g., CaO), ferric oxide (Fe₂O₃), magnesium oxide (MgO), boron oxide (B₂O₃), chromium oxide (Cr₂O₃), zirconium oxide (ZrO), silicon nitride (e.g., Si₃N₄), silicon carbide (e.g., SiC), alkalies (e.g., Na₂O), or any other ceramic material, or any combinations thereof. The term “ceramic” is used herein to refer to any inorganic, nonmetallic material. In one preferred embodiment, the liner 124 comprises a sheet of fibrous ceramic, e.g., having a thickness of about ⅛ inch. Sheets of fibrous ceramic are commercially available from Thermal Ceramics Americas, which is located in Augusta, Ga., U.S.A.

In some embodiments, the choice of liner material is guided by matching the thermal expansion coefficient of the liner as closely as possible to the thermal expansion coefficient of the material that is to be sputter deposited. Thus, certain embodiments involve a chamber adapted to sputter deposit a material having a known thermal expansion coefficient, wherein the chamber is provided with a liner comprising material (e.g., fibers) having a thermal expansion coefficient that is substantially equal to (e.g., less than 20% different, preferably less than 15% different, more preferably less than 10% different, and perhaps optimally identical to) that of the material to be sputter deposited.

In some embodiments, the liner 124 comprises a plurality of mineral wool fibers (e.g., rock wool, slag wool, or fiberglass). In one embodiment, the liner 124 is formed of a sheet of rock wool having a thickness of about ⅛ inch. Rock wool and other mineral wools are commercially available from well known suppliers (e.g., Vesuvius USA Corp.).

While ceramic liner materials have been found to be particularly advantageous, the invention in certain embodiments provides liners comprising metallic fibers. These liners have unique benefits. In certain embodiments, the liner 124 comprises a plurality of metal alloy fibers. Various metal alloy fibers can be used. In certain preferred embodiments, the metal alloy fibers include stainless steel fibers. In one embodiment, substantially all of the fibers in the liner are stainless steel. Stainless steel fibers and other metal alloy fibers are commercially available from a variety of sources. For example, stainless steel fibers are commercially available from variety of well known suppliers, such as NIPPON SEISEN Co., Ltd. (Osaka, Japan). Stainless steel fibers are sold by NIPPON SEISEN Co., Ltd. under the trade name NASLON. Stainless steel fibers are also sold by Bekaert under the trade name Bekipor®.

In certain preferred embodiments, the liner comprises material having a thermal expansion coefficient that is substantially the same as that of the material being sputter deposited. Spalling of sputtered material from a liner is believed to be minimized when the liner is formed of a material that thermally expands and contracts at a rate equal, or as close as possible, to that of the sputter deposited material. For example, when a sputtered metallic film is deposited, it may be preferable to employ a liner comprising metallic (i.e., a pure metal or metal alloy) material. Generally speaking, metals have thermal expansion coefficients in the range of between about 12×10⁻⁶/° K. and about 30×10⁻⁶/° K. Thus, when a metallic film is sputter deposited, the liner can comprise a metallic material (e.g., fibers of a pure metal or a metal alloy, such as stainless steel).

As noted above, the liner can advantageously comprise a ceramic material (e.g., ceramic fibers and/or a ceramic plate). For example, a liner 124 of this nature can be used advantageously when depositing a sputtered ceramic coating, or any coating material having a low thermal expansion coefficient. Thus, in one embodiment, a liner 124 comprising ceramic material is positioned adjacent a selected interior surface of a sputtering chamber 100 adapted to deposit a sputtered ceramic coating (e.g., a dielectric film). In this embodiment, the ceramic material (e.g., ceramic fibers and/or a ceramic plate) of the liner 124 preferably has a thermal expansion coefficient of less than about 12×10⁻⁶/° K. More preferably, this material has a thermal expansion coefficient of less than about 8×10⁻⁶/° K., and perhaps optimally less than about 6×10⁻⁶/° K. In some cases, the thermal expansion coefficient is greater than about 1×10⁻⁶/° K. and less than one the coefficient maximums noted in this paragraph.

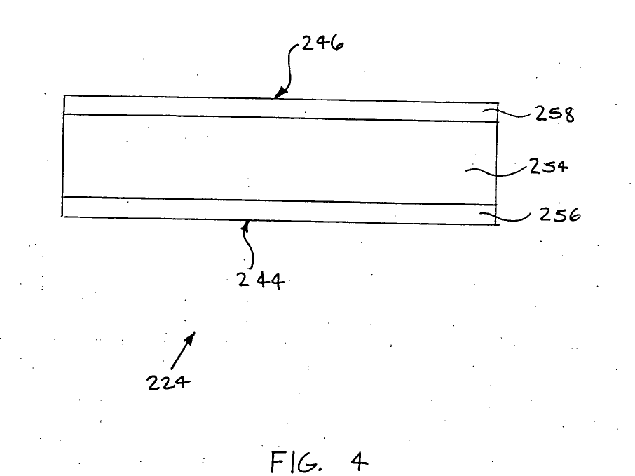

FIG. 4 is a cross-sectional view of an additional embodiment of a liner 224 in accordance with the present invention. In the embodiment of FIG. 4, the liner 224 includes a central core 254 interposed between a first facing layer 256 and a second facing layer 258. The first facing layer 256 defines the first major surface 244 of the liner 224 and the second facing layer 258 defines the second major surface 246 of the liner 224. Preferably, the core 254 is non-rigid (e.g., soft and pliable), such that it yields freely to expansion and contraction of the first 256 and second 258 facing layers at different rates (e.g., when the first facing layer is covered with sputtered material having a different thermal expansion coefficient than that of the material from which the second facing layer 258 of the liner is formed and/or that of the material from which the core is formed and/or that of the material from which the first facing layer is formed). In some embodiments, the core is a deformable core. The core 254 can advantageously comprise a mat (e.g., a soft mat) of fibrous material. If so desired, the central core 254 can have a different composition than the facing layers 256, 258. In some embodiments, the facing layers 256, 258 comprise at least one material (e.g., fibers of a desired material) that the core 254 also comprises. For example, the liner 224 can be made by treating surfaces of a mass of loose fibers with a binder (e.g., sodium silicate) in such a way that the binder does not reach the interior of the fiber mass. Thus, the facing layers 256, 258 may simply be surface regions that have been treated with a particular fiber-retaining binder, while the core 254 comprises fibers that have not been treated with that particular binder.

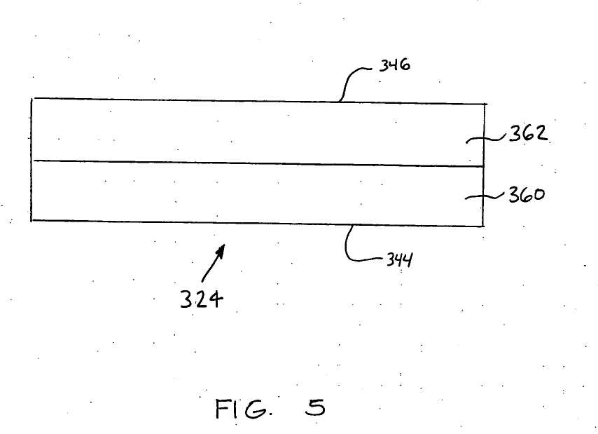

FIG. 5 is a cross-sectional view of another embodiment of a liner 324 in accordance with the invention. In this embodiment, the liner 324 comprises multiple layers. The illustrated liner 324 consist of a first layer 360 and a second layer 362. However, the liner 324 can be provided with any number of layers. The first layer 360 defines the first major surface or face 344 of the liner 324 and the second layer 362 defines the second major surface or face 346 of the liner 324. In some embodiments, at least one of the two layers 360, 362 (preferably the first layer 360) has a non-rigid structure, e.g., which preferably allows the liner 324 to yield readily to expansion and contraction of condensate on the liner. For example, one or both of the layers 360, 362 can be advantageously formed of a soft mat of fibrous material.

The liner can be mounted adjacent a selected interior surface of a sputtering chamber using any desired fasteners. For example, one or more conventional fasteners can be used, such as screws, bolts, slots, washers, clips, clamps, hook and loop, and/or other suitable fasteners, or any combination thereof. If so desired, conventional vacuum bolts (which are designed to avoid gas-trapping) can be used. Preferably, the fasteners are formed of a rigid material (e.g., a metal or metal alloy). In one embodiment, the fasteners are formed of a material having a thermal expansion coefficient that is substantially the same as that of the liner and/or of the material to be sputter deposited. In some embodiments, the fasteners are formed of a material that enables sputtered material to adhere to its surface particularly well. For example, it has been found that sputtered material adheres particularly well to aluminum. Thus, in certain preferred embodiments, the liner is mounted using at least one fastener comprising aluminum (e.g., having at least one exposed surface defined by aluminum). In some cases, the liner is mounted using a plurality of fasteners comprising (e.g., including, consisting essentially of, or consisting of) aluminum. Aluminum is particularly desirable, for instance, because it is particularly easy to roughen, and because many commonly-sputtered materials readily form aluminum compounds.

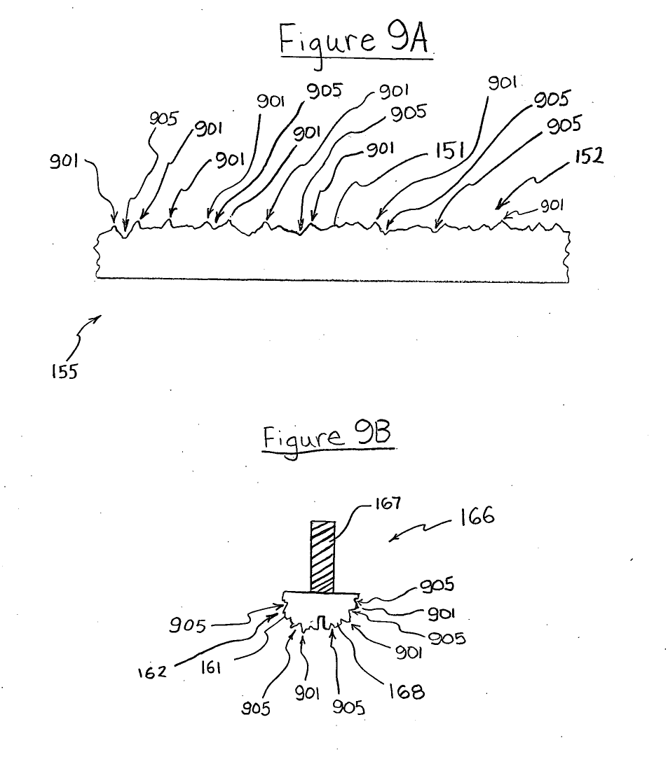

Further, it has been found that sputtered material adheres particularly well to surfaces that have been roughened (e.g., by sand blasting and/or by initially forming the surfaces so as to have a desired roughness). Thus, in some (though not all) embodiments, the fasteners have one or more roughened surfaces. In some cases, the fasteners each have at least one roughened surface. This is perhaps best understood with reference to FIGS. 9A-9B, wherein each illustrated fastener 155, 166 has a surface 151, 161 that is a roughened surface 152, 162. Here, the roughened surface 152, 162 has a plurality of spaced-apart peaks 901 and valleys 905. The illustrated peaks 901 and valleys 905 are irregularly sized, irregularly shaped, and irregularly spaced, although this is by no means required.

The surface roughness of each roughened fastener surface can be selected and varied as desired. In some cases, the average surface roughness Rₐ is at least about 1 micron, preferably at least about 1.3 microns, perhaps more preferably at least about 1.75 microns, and perhaps optimally at least about 2 microns. In certain embodiments, the average surface roughness Rₐ is at least about 3 microns. Reference is made to ASME B46.1-2002, the entire contents of which are incorporated herein by reference. In some cases, only exposed fastener surfaces are roughened. In a particularly preferred embodiment, the fasteners are formed of aluminum and each have at least one exposed surface that is roughened.

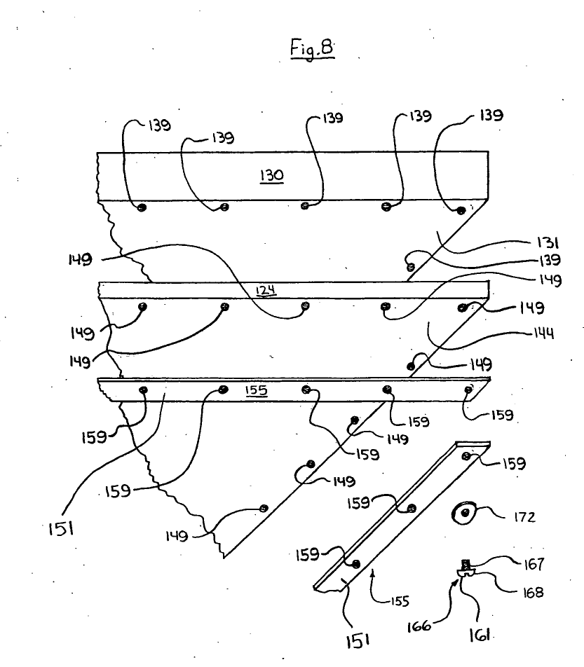

FIG. 8 illustrates a particularly preferred assembly for mounting a liner to an interior surface of a sputtering chamber. In the embodiment of FIG. 8, the liner 124 is carried adjacent the ceiling 130 of a sputtering chamber. A fastening assembly of the illustrated nature can be used to mount a liner adjacent any desired chamber surface.

With continued reference to FIG. 8, the liner 124 is retained in a sandwiched configuration between the interior surface 131 of the chamber ceiling 130 and at least one fastening bar (e.g., a plurality of fastening bars) 155. If so desired, there could be provided an appropriately shaped (e.g., rectangular) single fastening bar. Preferably, the interior surface 131 of the chamber ceiling 130 has (e.g., defines) a plurality of interiorly-threaded holes 139 formed along its perimeter. Each hole 139 is preferably adapted to receive a correspondingly-dimensioned, exteriorly-threaded fastener 166. The liner 124 also preferably has (e.g., defines) a plurality of spaced-apart holes 149 formed along its perimeter. The holes 149 in the liner 124 preferably have the same spacing and positioning as those in the chamber ceiling 130. Thus, the liner 124 preferably can be positioned against the chamber ceiling 130 such that the holes 149 in the liner 124 are aligned with those 139 in the chamber ceiling 130. The fastening bars 155 can then be positioned along the perimeter of the liner 124. Each fastening bar 155 preferably also has (e.g., defines) a plurality of spaced-apart holes 159. These holes 159 preferably have the same spacing as those in the liner 124 and those in the chamber ceiling 130. Thus, the fastening bars 155 preferably can be positioned against the first major surface 144 of the liner 124 such that the holes 159 in the fastening bars 155 are aligned with those in the liner 124 and those in the chamber ceiling 130. Threaded fasteners 166 can then be extended through the aligned holes in the fastening bars 155 and the liner 124 and into those 149 in the chamber ceiling 130.

The fastener 166 can be a screw, bolt, or the like. The fastener 166 can be made of any suitable material, e.g., a rigid material such as a metal or metal alloy. In some cases, the fastener 166 comprises, consists essentially of, or is formed of aluminum or another material, which optionally is roughened so as to enable sputtered material to better adhere to its exposed surface(s). Perhaps optimally, the fastener 166 is formed of aluminum and has one or more of its surfaces roughened, as described.

In preferred embodiments, the fastener 166 has an exteriorly-threaded shaft 167 and an enlarged head 168. Thus, when the fastener shafts 167 are threadingly advanced into the holes 139 in the chamber ceiling 130, the enlarged fastener heads 168 bear against the fastening bars 155, which bars 155 in turn keep the liner 124 sandwiched against the chamber ceiling. Preferably, the threaded shaft 177 of each fastener 166 has an outer diameter that is significantly smaller than the inner diameter of the holes 149 in the liner 124, so as to allow expansion and contraction of the liner 124 without restriction from the fasteners 166. The fasteners 166 are optionally used with washers 172.

The optional fastening bar(s) 155 can be formed of any desired material. Preferably, each bar 155 is formed of a rigid material (e.g., a metal or metal alloy). In one embodiment, each fastening bar 155 is formed of a material having a thermal expansion coefficient that is substantially the same as that of the liner 124 and/or that of the material to be sputter deposited. This may be preferable to minimize spalling of sputtered material from the fastening bars. Each fastener bar 155 can be formed of a material that enables sputtered material to adhere particularly well to its exposed surface(s). Thus, in certain embodiments, each fastening bar 155 comprises, consists essentially of, or consists of aluminum. In some cases, each fastening bar comprises aluminum defining at least one roughened surface, as described above. Perhaps optimally, each fastening bar 155 consists essentially of, or is formed of, aluminum and has one or more roughened surfaces.

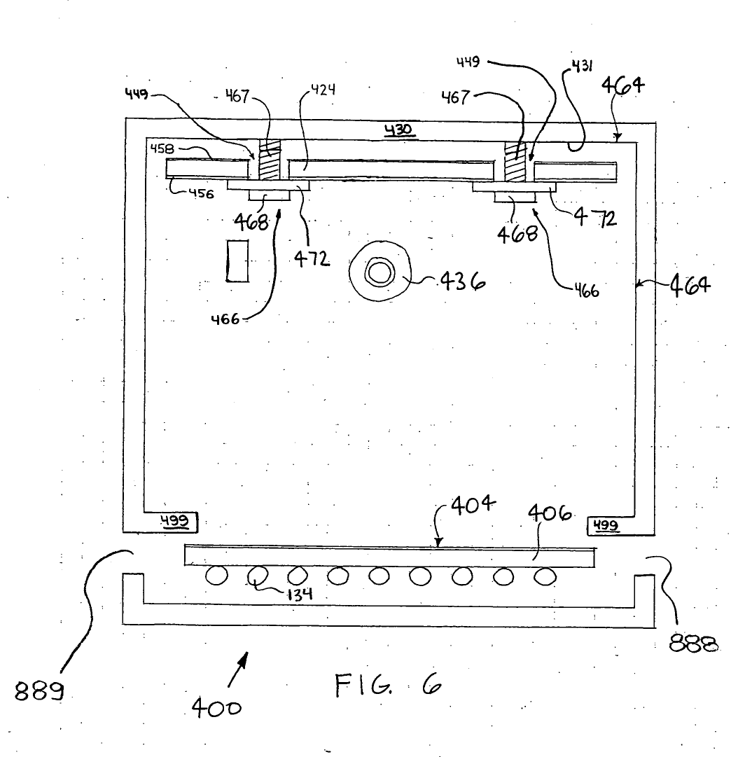

FIG. 6 illustrates another embodiment of the invention wherein a liner 424 is mounted adjacent the ceiling 464 of a sputtering chamber 400. As noted above, mounting a liner adjacent the ceiling of a sputtering chamber is advantageous since flakes of spalling condensate from the ceiling tend to fall downward toward the path of substrate travel without being caught by any upward-facing surface. Flakes of spalling condensate from the sidewalls of a chamber are more likely to be caught by side shields 499 (when present), as can be appreciated with reference to FIG. 6.

Thus, in certain embodiments, the liner is mounted adjacent a wall (which defines the selected surface) of the chamber that is directly above a path of substrate travel (such that substrates pass directly underneath this wall when conveyed through the chamber during sputtering).

It may be preferable to provide space between the liner and the underlying chamber wall. For example, depending upon the porosity of the liner, the liner may trap gas to some extent if the liner is secured directly against the chamber wall. Therefore, to facilitate chamber degassing, it may be preferable if the liner is mounted in a position where it is spaced apart from the underlying chamber wall.

Thus, in the embodiment of FIG. 6, the liner 424 is spaced apart from (e.g., suspended below) the ceiling 430 of the sputtering chamber 400. The liner 424 is retained in the illustrated configuration using bolts 466 with enlarged heads 468 (e.g., acorn bolts can be used). The threaded shafts 467 of the bolts have a diameter that is significantly smaller than that of the liner holes 449 through which they pass. This allows the liner 424 to freely contract and expand without restriction from the bolts. The bolts 466 are advantageously used with washers 472 (or other plates having a width dimension greater than a width dimension of the liner holes), particularly when the holes 449 in the liner 424 are substantially greater in diameter than the enlarged heads 468 of the fasteners 466. While the illustrated liner 424 is suspended below the chamber ceiling 430, a mounting assembly of this nature can alternatively be used to retain the liner 424 directly against the interior surface 431 of the chamber ceiling 430.

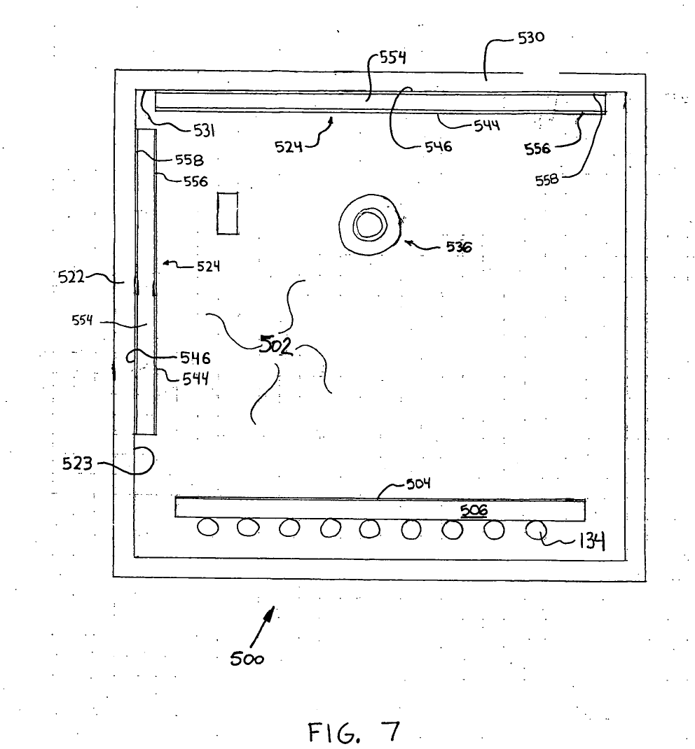

FIG. 7 illustrates an embodiment of the invention in which a sputtering chamber 500 is provided with two liners 524. The illustrated liners 524 are carried directly against the ceiling 530 and a sidewall 522 (which is directly above a path of substrate travel), respectively, of the chamber 500. In more detail, the second major surface 546 of the liner 524 on the ceiling 530 is contiguous to the interior surface 531 of the ceiling 530. Similarly, the second major surface 546 of the liner 524 on the sidewall 522 is contiguous to the interior surface 523 of the sidewall 522. The illustrated liners 524 each comprise a central core 554 interposed between first 556 and second 558 facing layers, as discussed above with reference to FIG. 4. This, however, is by no means required. For example, one or both liners 524 can alternatively be formed of a single layer or any other number of layers. This is also true of the liner 424 shown in FIG. 6.

Methods of the invention are perhaps best understood with reference to FIG. 1. Generally, the liner 124 can be used in any type of sputtering chamber 100. Preferably, the liner 124 is used in a sputtering chamber in which a controlled (e.g., vacuous) environment can be established and maintained. The liner 124 is mounted adjacent a selected interior surface of the chamber 100. A gaseous atmosphere is introduced into the cavity 102 of chamber 100. The method may involve reactive sputtering, which is carried out in a reactive atmosphere (such as oxygen), or non-reactive sputtering, which is carried out in an inert atmosphere (such as argon). The atmosphere used during sputtering can include any desired sputtering gas. Examples of suitable gases include argon, oxygen, nitrogen, helium, hydrogen, boron, and combinations thereof. In certain embodiments, the gaseous atmosphere in the sputtering chamber is, during sputtering, at a pressure of less than about 140 torr., and perhaps more preferably less than 0.1 torr. In one embodiment, the pressure is between about 1 mtorr. and about 0.1 torr., and perhaps more preferably between about 1 mtorr. and about 30 mtorr.

In certain embodiments, the chamber is adapted for depositing a dielectric film (e.g., a transparent dielectric film). In some such embodiments, the target comprises a sputterable ceramic material and/or the chamber contains a reactive gaseous atmosphere (e.g., oxygen and/or nitrogen), and the liner comprises a plurality of ceramic fibers.

The methods of the invention commonly involve creating an electric field in the chamber 100 to ionize the gaseous sputtering atmosphere and to establish a plasma in the cavity 102. As noted above, this causes charged plasma ions to strike the targets 136, 138, causing particles of target material 140 to be emitted from the targets. Due to backscattering, not all of the emitted particles are deposited upon the substrate 106. Rather, some of these particles land upon interior surfaces of the chamber 100, some being deposited upon the liner 124. Thus, a coating of sputtered material builds up on (e.g., is received by) the liner during sputtering.

The sputtered coating 104 can be any desired material without deviating from the spirit and scope of the invention. A wide variety of metallic films are deposited by sputtering, as are many oxides, nitrides, etc. Examples of metallic films that are commonly deposited by sputtering include silver, titanium, niobium, aluminum, nickel, chromium, stainless steel, and nickel chrome. Examples of sputtered oxides include zinc oxide, titanium oxide, niobium oxide, tin oxide, indium oxide, and silicon oxide. Examples of sputtered nitrides include silicon nitride, titanium nitride, and boron nitride. Other sputtered nitrides include nitrides of stainless steel, chromium, zirconium, tantalum, and hafnium. Examples of sputtered borides include borides of stainless steel, titanium, chromium, zirconium, tantalum, and hafnium. Examples of sputtered carbides include carbides of stainless steel, titanium, chromium, zirconium, tantalum, and hafnium.

Generally, metallic films are less problematic in terms of spalling, as metallic films tend to be more adhesive. However, the liner can be used when metallic films are deposited. In some embodiments of this nature, the liner comprises fibers formed of a metallic material (i.e., a pure metal or a metal alloy, such as stainless steel).

Thus, in certain methods, the sputtering chamber includes a target comprising a sputterable target material, which may be a metal or non-metal (e.g. a ceramic). Reactive gas (e.g., oxygen and/or nitrogen) is delivered to the sputtering cavity in some cases, whereupon a reaction product (e.g., a dielectric film) of the metal or non-metal can be deposited by sputtering the target. In other cases, a dielectric film is deposited by sputtering a ceramic target material in an inert gas.

In certain embodiments, the sputtered coating has a coefficient of thermal expansion of less than about 12×10⁻⁶° K., and perhaps more preferably less than about 10×10⁻⁶/° K. In some of these embodiments, the liner is comprised of material having a thermal expansion coefficient of less than about 12×10⁻⁶/° K., and perhaps more preferably less than about 10×10⁻⁶/° K. The liner material can comprise material having a thermal expansion coefficient of greater than about 1×10⁻⁶/° K. and less than one or more of the coefficient maximums noted in this paragraph. The coating may be a ceramic material, in which case the liner can advantageously comprise a ceramic material (e.g., ceramic fibers and/or a ceramic plate).

Liners of the invention are particularly advantageous in reducing spalling of overcoat from sputtering chambers. Thus, the present liners allow coated glass manufacturers to achieve particularly economic sputter deposition processes. The productivity of large, industrial-scale coaters is directly related to the down time required for target change-outs, chamber maintenance, and the length of time required for pumping down the coating chambers before sputtering is resumed (e.g., following target change-outs). The present liners reduce these periods of downtime. Moreover, the liner reduces the occurrence of spalling, and hence the coatings produced using the present liners are of particularly high quality (e.g., they are particularly free of pinholes and inclusions).

As noted above, the liners preferably are mounted removably in the chamber. The liners also preferably are disposable. Thus, each time a sputtering chamber is vented for maintenance, the overcoated liner or liners (optionally together with the fasteners used to mount the liners) can be removed from the chamber and disposed (and replaced before sputtering is started back up). Such liners require no cleaning, as compared to existing wire shields, which require removal, cleaning, and replacement. To the contrary, the present liners can be removed during maintenance periods and simply replaced with new liners. Thus, the present liners and/or fasteners can optionally be disposable. Similarly, certain methods of the invention involve disposing of the liner and/or fasteners during each target change-out. Thus, in some embodiments, the invention involves methods wherein the liners are periodically discarded and replaced.

Reference is made in the present disclosure to the thermal expansion coefficient of various materials. The term “thermal expansion coefficient” is used herein in accordance with its well known meaning. The term “dielectric” is used herein to refer to any non-metallic (i.e., neither a pure metal nor a metal alloy) compound that includes any one or more metals. Included in this definition, for example, is any metal oxide, metal nitride, metal carbide, metal sulfide, metal boride, metal fluoride, etc., and any combinations thereof (e.g., an oxynitride). Further, the term “metal” should be understood to include all metals and semi-metals (i.e., metalloids). Transparent dielectric film is substantially transparent (e.g., to visible radiation) when deposited as a thin film.

While there has been described what are believed to be preferred embodiments of the present invention, those skilled in the art will recognize that other and further changes and modifications may be made thereto without departing from the spirit of the invention, and it is intended to claim all such changes and modifications as fall within the true scope of the invention.

What is claimed is:

1. In a sputtering chamber for applying thin films onto substrates, the chamber having a sputtering cavity in which a controlled environment can be established, a target positioned in the sputtering cavity and adapted to deposit a sputtered material having a first thermal expansion rate, and a power supply operatively connected to the target to apply an electric charge to at least a portion of the target, the improvement comprising a removable liner positioned adjacent a selected interior surface of the chamber, the liner being adapted to receive an overcoat of the sputtered material that otherwise would be deposited on said selected interior surface of the chamber, the liner being adapted to expand and contract with the overcoat at said first thermal expansion rate without substantial spalling of particles of the overcoat from the liner.

2. The sputtering chamber of claim 1 wherein the liner is a flexible, soft liner.

3. The sputtering chamber of claim 1 wherein the liner comprises a mat of fibrous material.

4. The sputtering chamber of claim 1 wherein the liner comprises a non-woven web of fibers.

5. The sputtering chamber of claim 4 wherein the fibers are disposed in a substantially randomly intertangled manner.

6. The sputtering chamber of claim 5 wherein the randomly intertangled fibers define a plurality of interstitial spaces.

7. The sputtering chamber of claim 1 wherein the liner comprises a fabric of interwoven fibers.

8. The sputtering chamber of claim 1 wherein the liner comprises a plurality of ceramic fibers.

9. The sputtering chamber of claim 8 wherein the liner comprises a plurality of refractory ceramic fibers.

10. The sputtering chamber of claim 1 wherein the liner comprises a plurality of metal alloy fibers.

11. The sputtering chamber of claim 10 wherein the liner comprises a plurality of stainless steel fibers.

12. The sputtering chamber of claim 1 wherein the liner comprises a mineral wool selected from the group consisting of rock wool, slag wool, and fiberglass.

13. The sputtering chamber of claim 1 wherein said selected interior surface is located directly above a path of substrate travel.

14. The sputtering chamber of claim 13 wherein said selected interior surface is defined by a ceiling of the chamber.

15. The sputtering chamber of claim 14 wherein said selected interior surface comprises a central surface region defined by the chamber's ceiling, wherein two rotary targets are mounted below the chamber's ceiling, the targets being spaced apart such that adjacent the central surface region the liner is exposed to material sputtered in the chamber.

16. The sputtering chamber of claim 13 wherein said selected interior surface is a sidewall of the chamber.

17. A sputtering chamber for applying thin films onto substrates, comprising:
a) a sputtering cavity in which a controlled environment can be established;
b) a target positioned in the sputtering cavity and adapted to deposit a sputtered coating having a first thermal expansion rate;
c) a power supply operatively connected to the target for applying an electric charge to at least a portion of the target; and
d) a removable liner positioned adjacent a selected interior surface of the chamber, the liner being adapted to receive an overcoat of the sputtered coating that otherwise would be deposited on said selected interior surface of the chamber, the liner being adapted to expand and contract with the overcoat at said first thermal expansion rate without substantial spalling of particles of the overcoat from the liner.

18. The sputtering chamber of claim 17 wherein said selected interior surface is defined by a ceiling of the chamber, said selected interior surface comprising a central surface region defined by the chamber's ceiling, wherein two rotary targets are mounted below the chamber's ceiling, the targets being spaced apart such that adjacent the central surface region the liner is exposed to material sputtered in the chamber.

19. The sputtering chamber of claim 17 wherein the target comprises a sputterable ceramic material and/or the chamber contains a reactive gaseous atmosphere, and wherein the liner comprises a plurality of ceramic fibers.

20. The sputtering chamber of claim 17 wherein the liner is mounted adjacent said selected interior surface by at least one aluminum fastener having a roughened surface exposed to material sputtered in the chamber.

21. The sputtering chamber of claim 20 wherein the roughened surface has an average surface roughness Rₐ of at least about 1.3 microns.

22. A sputtering chamber for applying thin films onto substrates, the chamber having a sputtering cavity in which a controlled environment can be established, the chamber including a target positioned in the cavity, the target being operatively connected to a power supply adapted to apply an electric charge to at least a portion of the target, the chamber including a removable liner positioned adjacent a selected interior surface of the chamber, the liner comprising a mat of fibrous material.

23. A sputtering chamber for applying thin films onto substrates, the chamber having a sputtering cavity in which a controlled environment can be established, the chamber including a target positioned in the cavity, the target being operatively connected to a power supply adapted to apply an electric charge to at least a portion of the target, the chamber including a removable liner positioned adjacent a selected interior surface of the chamber, the liner comprising a non-woven web of fibers.

24. A sputtering chamber for applying thin films onto substrates, the chamber having a sputtering cavity in which there is established a controlled environment comprising a sputtering gas, the chamber including a target positioned in the cavity, the target comprising a sputterable target material selected in conjunction with said sputtering gas to facilitate deposition of a dielectric film, the chamber including a power supply operatively connected to the target to apply an electric charge to at least a portion of the target, wherein a removable liner positioned adjacent a selected interior surface of the chamber is adapted to catch an overcoat of the dielectric film, which overcoat otherwise would be deposited on said selected interior surface of the chamber, the liner comprising a plurality of ceramic fibers.

25. A sputtering chamber for applying thin films onto substrates, the chamber having a sputtering cavity in which a controlled environment can be established, the chamber including a target positioned in the cavity, the target being operatively connected to a power supply adapted to apply an electric charge to at least a portion of the target, the chamber including a removable liner positioned adjacent a selected interior surface of the chamber, the liner comprising a plurality of metal alloy fibers.

26. The sputtering chamber of claim 25 wherein the liner comprises a plurality of stainless steel fibers.

27. A method of applying thin films onto substrates, the method comprising:
a) providing a sputtering chamber having a sputtering cavity in which there is established a controlled environment comprising a sputtering gas, the chamber including a target positioned in the cavity, the target being adapted to deposit a sputtered material, the chamber including a power supply operatively connected to the target to apply an electric charge to at least a portion of the target, the chamber including at least one substrate support carrying a substrate within the sputtering cavity, the chamber including a removable liner positioned adjacent a selected interior surface of the chamber, the liner comprising a mat of fibrous material; and
b) sputtering the target to deposit a film of the sputtered material upon the substrate, thereby depositing an overcoat of the sputtered material on the liner.

28. The method of claim 27 wherein the liner comprises a plurality of ceramic fibers and the target comprises a sputterable material selected in conjunction with the sputtering gas to deposit said film as a dielectric film, the method comprising delivering the sputtering gas to the sputtering cavity.

29. The method of claim 28 wherein the target comprises a sputterable ceramic material and/or the sputtering gas delivered to the sputtering cavity is a reactive gas.

30. A sputtering chamber for applying thin films onto substrates, the chamber having a sputtering cavity in which a controlled environment can be established, the chamber including a target positioned in the cavity, the target being operatively connected to a power supply adapted to apply an electric charge to at least a portion of the target, the chamber including a removable liner positioned adjacent a selected interior surface of the chamber, the liner comprising a plurality of fibers.

31. The sputtering chamber of claim 30 wherein the liner comprises a plurality of fibers each having a diameter of less than about 300 micrometers.

32. The sputtering chamber of claim 31 wherein the diameter is less than about 50 micrometers.

33. The sputtering chamber of claim 32 wherein the diameter is less than about 30 micrometers.

34. The sputtering chamber of claim 30 wherein the liner is mounted adjacent said selected interior surface using a plurality of fasteners.

35. The sputtering chamber of claim 34 wherein the fasteners include at least one elongated fastening bar, the liner being sandwiched between the fastening bar and said selected interior surface of the chamber.

36. The sputtering chamber of claim 34 wherein the fasteners comprise aluminum.

37. The sputtering chamber of claim 34 wherein the fasteners are formed of a material having a thermal expansion coefficient that is substantially the same as that of the liner.

38. The sputtering chamber of claim 34 wherein the fasteners each have a roughened surface exposed to material sputtered in the chamber.

39. A sputtering chamber for applying thin films onto substrates, the chamber having a sputtering cavity in which a controlled environment can be established, the chamber including two rotary targets mounted in the cavity below a ceiling of the chamber, the targets being operatively connected to at least one power supply adapted to apply an electric charge to at least a portion of each target, the chamber including a removable liner positioned adjacent a selected interior surface of the chamber, said selected interior surface comprising a central surface region defined by the chamber's ceiling, the liner comprising a mat of fibrous material, wherein the two targets are spaced apart such that adjacent the central surface region the liner is exposed to material sputtered in the chamber, wherein the liner is mounted adjacent said selected interior surface by a plurality of aluminum fasteners each having a roughened surface exposed to material sputtered in the chamber.

40. The sputtering chamber of claim 39 wherein the roughened surface has an average surface roughness Rₐ of at least about 1 micron.

41. The sputtering chamber of claim 40 wherein the average surface roughness Rₐ is at least about 1.75 microns.

42. The sputtering chamber of claim 41 wherein the average surface roughness Rₐ is at least about 2 microns.

43. The sputtering chamber of claim 39 wherein the aluminum fasteners include at least one elongated aluminum fastening bar, the liner being sandwiched between the aluminum fastening bar and said selected interior surface of the chamber, the aluminum fastening bar having a roughened major surface exposed to material sputtered in the chamber.
